(19) United States
(12) Patent Application Publication
(10) Pub. No.: US 2024/0079855 A1
(43) Pub. Date: Mar. 7, 2024

(54) High-Speed Vertical Cavity Surface Emitting Laser, Electronic Device with the Same and Manufacturing Method Thereof

(71) Applicant: Shenzhen Berxel Photonics Co., Ltd., Shenzhen City (CN)

(72) Inventors: Jiaxing Wang, Shenzhen City (CN); Huawen Hu, Shenzhen City (CN)

(21) Appl. No.: 18/133,433

(22) Filed: Apr. 11, 2023

(30) Foreign Application Priority Data
Sep. 5, 2022 (CN) 202211077441.2

(51) Int. Cl. H01S 5/183; H01S 5/42

(52) U.S. Cl. CPC H01S 5/18372; H01S 5/18311; H01S 5/423

(57) ABSTRACT

The present disclosure provides a high-speed vertical cavity surface emitting laser, an electronic device with the same, and a manufacturing method thereof. The high-speed vertical cavity surface emitting laser includes a substrate layer, a first electrode layer, a first reflector layer, an active layer, an oxide-confined layer, a second reflector layer and a second electrode layer, wherein the oxidation aperture in the oxide-confined layer is a polygon having imperfect symmetry.

### CROSS REFERENCE TO RELATED APPLICATION

The present disclosure claims the benefit of priorities to Chinese patent application No. 202211077441.2, filed on Sep. 5, 2022 to China National Intellectual Property Administration, which is incorporated herein by reference in its entirety.

### TECHNICAL FIELD

The present disclosure generally relates to the technical field of photoelectric devices, in particular, to a high-speed vertical cavity surface emitting laser, an electronic device with the same, and a manufacturing method thereof.

### BACKGROUND

A vertical cavity surface emitting laser (VCSEL) can be widely applied to the fields such as optical communication, 3D sensing, and laser radar due to various advantages such as a small size, low power consumption, simplicity in integration, high coupling efficiency and a round beam shape output.

Since the shape of oxidation apertures in the oxide-confined layer of the VCSEL may affect the mode of the laser, and further affect other key properties such as relative intensity noise (RIN), and root mean square (RMS) spectral width, etc. So far, in the related art, the oxidation apertures in VSCELs generally have the shape of a circle, which has a super rotational symmetry. This may cause two or even more degenerated modes easily to appear at one frequency point, and there exists a mode competition among these degenerated modes, which causes an increased mode partition noise (MPN) and thus leads to an increased RIN, meanwhile the consistency of RIN and RMS spectral width degrades. Accordingly an increased bit error ratio (BER) in communication system will be caused and the communication quality is badly affected.

### SUMMARY

In view of above-mentioned defects or disadvantages in the related art, it is desired to provide a high-speed vertical cavity surface emitting laser, an electronic device with the same, and a manufacturing method thereof, so as to reduce the relative intensity noise of the laser and improve the consistency of relative intensity noise and root mean square spectral width at the same time, thereby solving the technical problems such as increased bit error ratios due to a high relative intensity noise and a larger chromatic dispersion.

In a first aspect, the present disclosure provides a high speed vertical cavity surface emitting laser, wherein the high-speed vertical cavity surface emitting laser includes a substrate layer, a first electrode layer, a first reflector layer, an active layer, an oxide-confined layer, a second reflector layer, and a second electrode layer, wherein the oxidation aperture in the oxide-confined layer has the shape of a polygon having imperfect symmetry.

Optionally, in some embodiments of the present disclosure, the oxidation aperture is disposed in the middle of the oxide-confined layer.

Optionally, in some embodiments of the present disclosure, the first electrode layer is located under the substrate layer, and the first reflector layer, the active layer, the oxide-confined layer, the second reflector layer and the second electrode layer are sequentially stacked on the substrate layer.

Optionally, in some embodiments of the present disclosure, the first reflector layer and the second reflector layer include at least one of a distributed Bragg reflector layer and a high contrast grating layer.

Optionally, in some embodiments of the present disclosure, the first electrode layer and the second electrode layer respectively include any one of a N-type electrode layer and a P-type electrode layer.

Optionally, in some embodiments of the present disclosure, the active layer includes any one of a single quantum well layer and a multiple quantum well layer.

In a second aspect, the present disclosure provides an electronic device, wherein the electronic device includes the high-speed vertical cavity surface emitting laser of any one in the first aspect.

In a third aspect, the present disclosure provides a manufacturing method for a high-speed vertical cavity surface emitting laser, wherein the method is applied to the high-speed vertical cavity surface emitting laser of any one in the first aspect, and the method includes:
Providing a substrate layer, and sequentially forming a first reflector layer, an active layer, an oxide-confined layer and a second reflector layer on the substrate layer;
Disposing a plurality of trenches, and exposing the oxide-confined layer by etching, and performing partially oxidation on the oxide-confined layer to obtain an oxidation aperture in polygon having imperfect symmetry.

Filling the etched trenches with a metal, and forming a first electrode layer on the substrate layer, and forming a second electrode layer on the second reflector layer.

Optionally, in some embodiments of the present disclosure, the distances among the trenches are equal or unequal.

It can be seen from the above-mentioned technical solutions, the embodiments of the present disclosure have the following advantages:

The embodiments of the present disclosure provide a high-speed vertical cavity surface emitting laser, an electronic device with the same, and a manufacturing method thereof. By designing the oxidation apertures of the oxide-confined layer of the high-speed vertical cavity surface emitting laser to be polygon having imperfect symmetry, it breaks through the design of rotational symmetry in the distribution of circular oxidation apertures, reduces the possibility that a plural degenerated modes appear at one frequency point. Furthermore, it can reduce the relative intensity noise of the laser, enhance the consistency of relative intensity noise and root mean square spectral width, and significantly improve the communication quality.

### BRIEF DESCRIPTION OF FIGURES

By reading detailed descriptions of nonrestrictive embodiments with reference to the accompanying drawings, other features, objectives and advantages of the present disclosure will become more apparent.

FIG. 1 is a schematic diagram of a sectional structure of a high-speed VCSEL provided in an embodiment of the present disclosure.

FIG. 2 shows a top view of the oxidation aperture zone in the high-speed VCSEL having a circular oxidation aperture in the related art, and the corresponding spectrum distribution chart.

FIG. 3 shows a top view of the oxidation aperture zone in the high-speed VCSEL having an oxidation aperture in pentagon having imperfect symmetry provided by an embodiment of the present disclosure, and the corresponding spectrum distribution chart.

FIG. 4 is a box-plot contrast diagram of RIN of a high-speed VCSEL having a circular oxidation aperture in the related art, and RIN of a high-speed VCSEL having an oxidation aperture in pentagon having imperfect symmetry as provided in an embodiment of the present disclosure.

FIG. 5 is a box-plot contrast chart of RMS spectral width of a high-speed VCSEL having a circular oxidation aperture in the related art, and RMS spectral width of a high-speed VCSEL having an oxidation aperture in pentagon having imperfect symmetry as provided in an embodiment of the present disclosure.

FIG. 6 is a structural block diagram of an electronic device provided in an embodiment of the present disclosure.

FIG. 7 is a flow diagram of a basic process of a manufacturing method for a high-speed VCSEL provided in an embodiment of the present disclosure.

FIG. 8 shows top views of the several oxidation apertures in the high-speed VCSEL provided in an embodiment of the present disclosure, and the schematic diagram of the corresponding near-filed beam patterns.

### REFERENCE NUMERALS

100, a high-speed vertical cavity surface emitting laser;
101, a substrate layer;
102, a first electrode layer;
103, a first reflector layer;
104, an active layer;
105, an oxide-confined layer;
1051, an oxidation aperture;
106, a second reflector layer;
107, a second electrode layer;
200, an electronic device

### DETAILED DESCRIPTION

In order to make the skilled in the art better understand solutions in the present disclosure, the technical solutions in the embodiments of the present disclosure will be described clearly and completely below in conjunction with the accompanying drawings in the embodiments of the present disclosure. Obviously, the described embodiments are only a part of the embodiments of the present disclosure, but not all the embodiments. Based on the embodiments of the present disclosure, all other embodiments obtained by those of ordinary skill in the art without creative work will fall within the protection scope of the present disclosure.

Terms “first”, “second”, “third”, “fourth”, etc. (if available) in the specification and claims of the present disclosure and the above-mentioned accompanying drawings are used for distinguishing similar objects, but are not required to describe a specific sequential or chronological order. It should be understood that data used in such a way are interchangeable under appropriate circumstances, such that the embodiments of the present disclosure described herein can be implemented in other sequences, in addition to the sequences illustrated or described herein.

In addition, terms “including” and “having” and any variants thereof are intended to cover non-exclusive inclusion. For example, a process, method, system, product or device including a series of steps or modules are unnecessarily limited to the clear listing of those steps or modules, but may include other steps or modules which are not clearly listed or are inherent for the process, method, product or device.

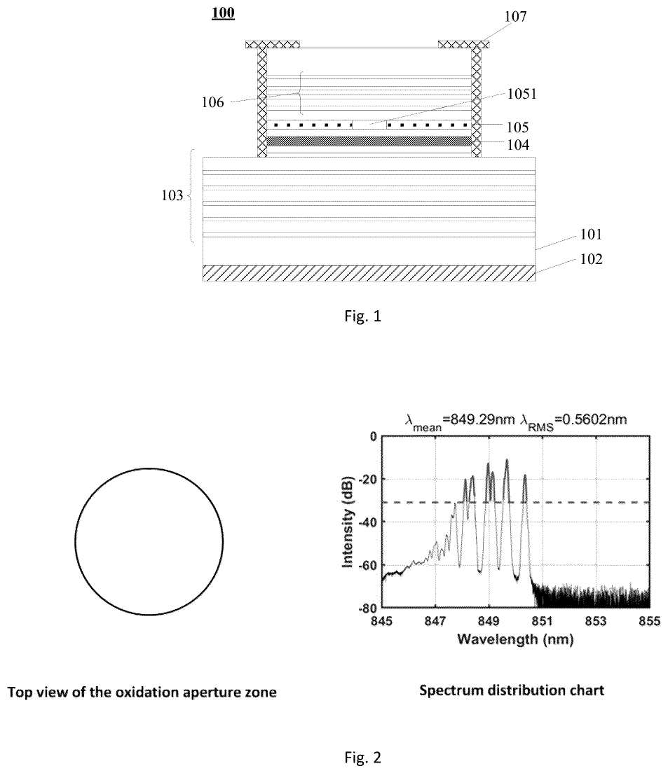

In order to better understand and describe the present disclosure, it shall describe a high-speed vertical cavity surface emitting laser, an electronic device with the same, and a manufacturing method thereof provided by embodiments of the present disclosure with reference to FIG. 1-FIG. 8.

Referring to FIG. 1, it is a schematic diagram of a sectional structure of a high-speed VCSEL provided in an embodiment of the present disclosure. The high-speed VCSEL 100 includes a substrate layer 101, a first electrode layer 102, a first reflector layer 103, an active layer 104, an oxide-confined layer 105, a second reflector layer 106, and a second electrode layer 107.

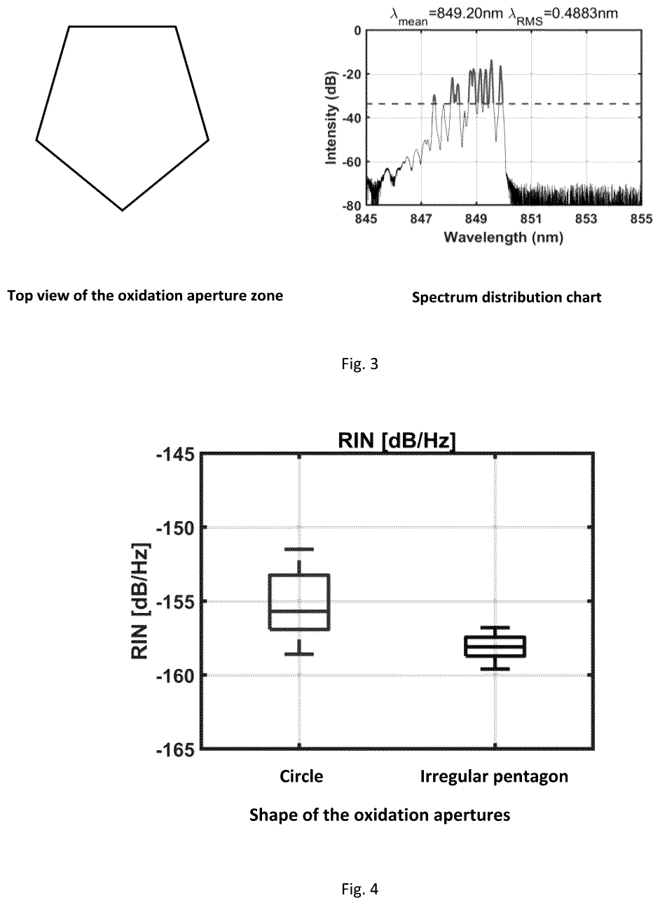

The oxidation aperture in the oxide-confined layer 105 has the shape of a polygon having imperfect symmetry. For example, the polygon includes, but is not limited to, tetragon, pentagon, hexagon, etc. Optionally, in the embodiment of the present disclosure, the oxidation aperture 1051 is disposed in the middle of the oxide-confined layer 1051. Taking the pentagon as an example of the polygon, as shown in FIG. 2, it shows a top view of the oxidation aperture zone in the VCSEL having circular oxidation apertures in the related art, and the corresponding spectrum distribution chart. FIG. 3 shows a top view of the oxidation aperture zone in the high-speed VCSEL having an oxidation aperture in pentagon having imperfect symmetry provided by an embodiment of the present disclosure, and the corresponding spectrum chart, wherein the horizontal coordinate represents wavelength, the vertical coordinate represents luminescence intensity. In combination with FIG. 2 and FIG. 3, it can be seen that, the pentagon oxidation aperture having imperfect symmetry breaks through the design of rotational symmetry in the distributed mode of circular oxidation aperture, allows the degenerated modes to be separated, and thus prevents plural degenerated modes from appearing at one frequency point.

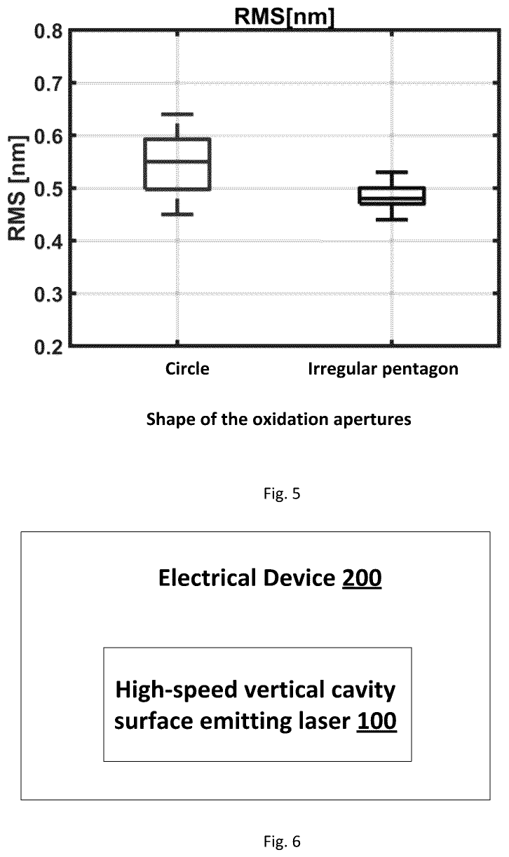

Furthermore, FIG. 4 shows a box-plot contrast chart of RIN of a high-speed VCSEL having circular oxidation apertures in the related art, and RIN of a high-speed VCSEL having oxidation apertures in pentagon having imperfect symmetry as provided in an embodiment of the present disclosure. And FIG. 5 shows a box-plot contrast chart of RMS spectral width of a high-speed VCSEL having circular oxidation apertures in the related art, and RMS spectral width of a high-speed VCSEL having oxidation apertures in pentagon having imperfect symmetry as provided in an embodiment of the present disclosure. In combination with FIG. 4 and FIG. 5, it can be seen that, the pentagon oxidation aperture having imperfect symmetry can reduce MPN, thus it effectively reduces RIN of the VCSEL, enhances the consistency of RIN and RMS spectral width, and significantly improves the communication quality.

Optionally, the high-speed VCSEL 100 provided in an embodiment of the present disclosure includes, but is not limited to a top emission structure and a bottom emission structure. Taking the top emission structure shown in FIG. 1 as an example, in this structure, the first electrode layer 102 is located under the substrate layer 101, and the first reflector layer 103, the active layer 104, the oxidation layer 105, the second reflector layer 106 and the second electrode layer 107 are sequentially stacked on the substrate layer 101.

Optionally, in the embodiment of the present disclosure, the first reflector layer 103 and the second reflector layer 106 may be any one of a N-type reflector layer and a P-type reflector layer. Furthermore, the first reflector layer 103 and the second reflector layer 106 may be at least one of a distributed Bragg reflector (DBR) layer and a high contrast grating (HCG) layer. That is to say, both of the first reflector layer 103 and the second reflector layer 106 are distributed Bragg reflectors, or both of the first reflector layer 103 and the second reflector layer 106 are high contrast gratings, or one of the first reflector layer 103 and the second reflector layer 106 is a distributed Bragg reflector, and the other is a high contrast grating.

Optionally, in the embodiment of the present disclosure, the first electrode layer 102 and the second electrode layer 107 may be any one of a N-type electrode layer and a P-type electrode layer.

Optionally, in the embodiment of the present disclosure, the active layer 104 may be any one of a single quantum well layer and a multiple quantum well (MQW) layer, and is used for emitting light when being electrified.

The embodiments of the present disclosure provide a high-speed VCSEL. By designing the shape of the oxidation apertures in the oxide-confined layer of the high-speed VCSEL to be polygon having imperfect symmetry, it breaks through the design of rotational symmetry in the distributed mode of circular oxidation apertures, reduces the possibility that plural degenerated modes appear at one frequency point. Furthermore, it can reduce the relative intensity noise of the laser, enhance the consistency of relative intensity noise and root mean square spectral width, and significantly improve the communication quality.

Based on the foregoing embodiments, referring to FIG. 6 which is a structural block diagram of an electronic device provided in an embodiment of the present disclosure. The electronic device 200 includes the high-speed VCSEL 100 in the embodiment corresponding to FIG. 1 to FIG. 5. In an example, electronic device 200 may include, but is not limited to an optical module, an integrated photoelectronic chip, etc.

An embodiment of the present disclosure provides an electronic device. By designing the shape of the oxidation aperture in the oxide-confined layer to be polygon having imperfect symmetry, in the high-speed VCSEL of the electronic device, it breaks through the design of rotational symmetry in the distributed mode of a circular oxidation aperture, reduces the possibility that plural degenerated modes appear at one frequency point. Furthermore, it can reduce the relative intensity noise of the laser, enhance the consistency of relative intensity noise and root mean square spectral width, and significantly improve the communication quality.

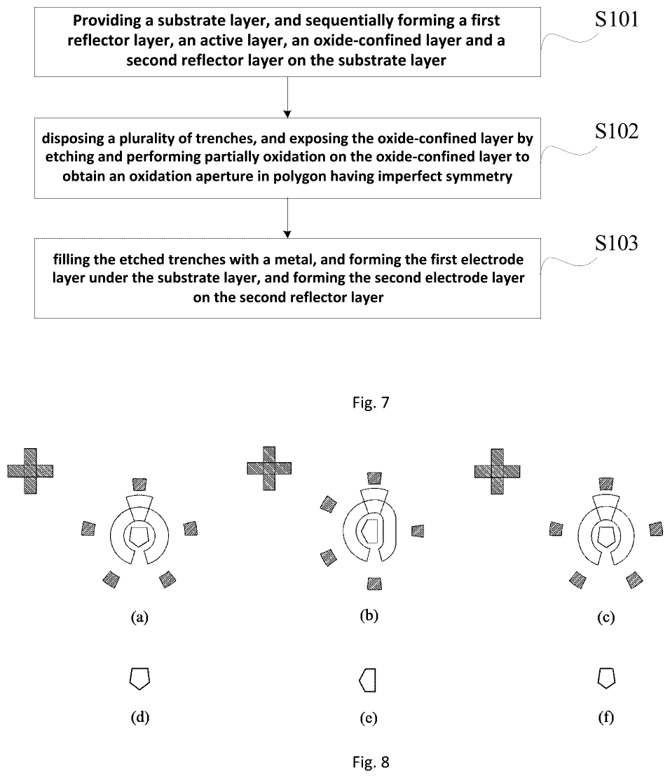

Based on the foregoing embodiment, referring to FIG. 7, which is a flow diagram of a basic process of a manufacturing method for a high-speed VCSEL provided in an embodiment of the present disclosure. This method can be applied to the vertical cavity surface emitting laser 100 in the embodiment corresponding to FIG. 1 to FIG. 5 and specifically includes the following steps:

S101, providing a substrate layer, and sequentially forming a first reflector layer, an active layer, an oxide-confined layer and a second reflector layer on the substrate layer.

Exemplarily, taking the structure shown in FIG. 1 as an example, a metal organic chemical vapor deposition (MOCVD) technology or a molecular beam epitaxy (MBE) technology, etc. are adopted for growing the first reflector layer 103, the active layer 104, the oxide-confined layer 105 having a high aluminum component Al_{0.98}Ga_{0.02}As, and the second reflector layer 106 on the substrate layer 101.

S102, disposing a plurality of trenches, and exposing the oxide-confined layer by etching and performing partially oxidation on the oxide-confined layer to obtain an oxidation aperture in polygon having imperfect symmetry.

Exemplarily, in the embodiments of the present disclosure, five trenches with equal intervals or unequal intervals may be disposed, that is, the distances among the trenches are equal or unequal. The patterns of the trenches may be obtained after etching, the oxide-confined layer 105 having a high aluminum component Al_{0.98}Ga_{0.02}As is exposed by inductively coupled plasma technique, and then the oxidation aperture 1051 in polygon having imperfect symmetry is obtained in a wet oxidation way, wherein the oxidation aperture 1051 is disposed in the middle of the oxide-confined layer 105 having a high aluminum component Al_{0.98}Ga_{0.02}As. As shown in FIG. 8, it shows top views of several oxidation apertures in high-speed VCSEL provided in an embodiment of the present disclosure, and the schematic diagram of the corresponding near-filed beam patterns. In the embodiment of the present disclosure, by disposing trenches in different positions, the oxidation apertures in different shapes of pentagon may be obtained. Meanwhile, by the oxidation way of disposing the five trenches, the stability and reliability of the high-speed VCSEL can be enhanced.

S103, filling the etched trenches with a metal, and forming the first electrode layer under the substrate layer, and forming the second electrode layer on the second reflector layer.

Exemplarily, in the embodiments of the present disclosure, the trenches may be filled with a metal by a magnetron sputtering way, and a N-type metal electrode corresponding to the first electrode layer 102 is obtained by a vapor plating process on electrodes, and a P-type metal electrode corresponding to the second electrode layer 106 is obtained by a magnetron sputtering way and a stripping process. Then, the laser having the plated electrodes was placed in a quick annealing furnace for annealing to achieve an alloy, thereby forming good ohmic contact between the electrodes and the semiconductor material, improving electrical properties of the device, and thus obtaining the high-speed VCSEL as shown in FIG. 1.

It should be noted that, the description for steps or contents in the present embodiment, which are the same as those in other embodiments, may refer to the description in other embodiments, but is not repeated here again.

An embodiment of the present disclosure provides a manufacturing method for a high-speed vertical cavity surface emitting laser. By designing the shape of the oxidation apertures in the oxide-confined layer of the high-speed vertical cavity surface emitting laser to be polygon having imperfect symmetry, it breaks through the design of rotation symmetry in the distributed mode of a circular oxidation aperture, reduces the possibility that plural degenerated modes appear at one frequency point. Furthermore, it can reduce the relative intensity noise of the laser, enhance the consistency of relative intensity noise and root mean square spectral width, and significantly improve the communication quality.

The above embodiments are merely intended to describe the technical solutions of the present disclosure, rather than to limit them. Although the present disclosure has been described in detail with reference to the aforementioned embodiments, it should be understood by those of ordinary skill in the art that they may still modify the technical solutions recited in each of the foregoing embodiments or equivalently substitute parts of technical features therein. These modifications or substitutions do not make the essences of the corresponding technical solutions depart from the spirit and scope of the technical solution in each of the embodiments of the present disclosure.

What is claimed is:

1. A high speed vertical cavity surface emitting laser, wherein the high-speed vertical cavity surface emitting laser includes a substrate layer, a first electrode layer, a first reflector layer, an active layer, an oxide-confined layer, a second reflector layer, and a second electrode layer, wherein the oxidation aperture in the oxide-confined layer has the shape of a polygon having imperfect symmetry.

2. The high speed vertical cavity surface emitting laser of claim 1, wherein the oxidation aperture is disposed in the middle of the oxide-confined layer.

3. The high speed vertical cavity surface emitting laser of claim 1, wherein the first electrode layer is located under the substrate layer, and the first reflector layer, the active layer, the oxide-confined layer, the second reflector layer and the second electrode layer are sequentially stacked on the substrate layer.

4. The high speed vertical cavity surface emitting laser of claim 3, wherein, the first reflector layer and the second reflector layer are at least one of a distributed Bragg reflector layer and a high contrast grating layer.

5. The high speed vertical cavity surface emitting laser of claim 4, wherein the first electrode layer and the second electrode layer respectively are any one of a N-type electrode layer and a P-type electrode layer.

6. The high speed vertical cavity surface emitting laser of claim 5, wherein the active layer is any one of a single quantum well layer and a multiple quantum well layer.

7. An electronic device, wherein the electronic device includes the high-speed vertical cavity surface emitting laser of claim 1.

8. A manufacturing method for a high-speed vertical cavity surface emitting laser, wherein the method is applied to the high-speed vertical cavity surface emitting laser of claim 1, and the method includes:
Providing a substrate layer, and sequentially forming a first reflector layer, an active layer, an oxide-confined layer and a second reflector layer on the substrate layer;
Disposing a plurality of trenches, and exposing the oxide-confined layer by etching, and performing partially oxidation on the oxide-confined layer to obtain an oxidation aperture in polygon having imperfect symmetry; and
Filling the etched trenches with a metal, and forming the first electrode layer on the substrate layer, and forming the second electrode layer on the second reflector layer.

9. The manufacturing method for a high-speed vertical cavity surface emitting laser of claim 8, wherein the distances among the trenches are equal or unequal.
